(19) United States
(12) Patent Application Publication
(10) Pub. No.: US 2002/0170171 A1
(43) Pub. Date: Nov. 21, 2002

(54) Multilayer printed circuit board and method for making the same

(76) Inventors: Hirohito Miyazaki, Kanagawa (JP); Yoshio Watanabe, Kanagawa (JP); Nobuyuki Yasuda, Kanagawa (JP)

Correspondence Address: RADER FISHMAN & GRAUER PLLC, LION BUILDING, 1233 20TH STREET N.W., SUITE 501, WASHINGTON, DC, 20036, US

(21) Appl. No.: 10/132,304

(22) Filed: Apr. 26, 2002

(30) Foreign Application Priority Data
May 7, 2001 (JP) P2001-136489

(51) Int. Cl. H05K 3/20; H05K 3/36; H05K 3/02

(52) U.S. Cl. 29/831; 29/830; 29/846

(57) ABSTRACT

A multilayer printed circuit board comprises core substrates, each having conductor patterns. The core substrates are laminated such that the conductor patterns of adjacent core substrates face each other. At least one insulating layer is provided between the core substrates to insulate the conductor patterns from each other. At least one connection lies between the core substrates, the connection connecting the conductor patterns with each other. The connection comprises an alloy comprising a first metal having a melting point below the heat resistant temperature of the core substrates and a second metal having a melting point above the heat resistant temperature. The connection is formed by thermal compression bonding of a bump of the first metal formed on a conductor pattern of one of the adjacent core substrates to a bump of the second metal formed on a conductor pattern of the other core substrate.

### BACKGROUND OF THE INVENTION

1. Field of the Invention

The present invention relates to multilayer printed circuit boards and methods for making the multilayer printed circuit boards.

2. Description of the Related Art

Compact lightweight electronic components require high-density printed circuit boards. Such high-density printed circuit boards are typically produced by a build-up process in which an insulating layer, a conductor pattern, and pits having small diameters are formed, an insulating connecting interlayer and a conductive pattern are formed, and then conductive layers are laminated. In the build-up process, the conductive layers are laminated one by one by repeating the same step, requiring much time. Furthermore, as the laminating step is repeated, the yield decreases and the conductive layers are not exactly aligned.

A method for solving the above problem is laminating the core substrates provided with conductor patterns that constitute conductive layers at a time. Referring to FIG. 10(A), in this one-stage process for forming a multilayer printed circuit board 50, conductor patterns 51 to 56 are formed on both faces of copper-lined core substrates 60 to 62, and plated through holes 57 to 59 for connecting the conductor patterns 51 to 56 are formed in the copper-lined core substrates 60 to 62.

Referring to FIG. 10(B), bumps 63 and 64 are formed by plating at predetermined positions of the corresponding conductor patterns 52 and 55, respectively, so as to electrically connect the conductor patterns 52 and 55 with the conductor patterns 53 and 54, respectively, formed on the core substrate 61. Next, prepregs 65 and 66 are placed on the core substrates 60 to 62. Referring to FIG. 10(C), the core substrates 60 to 62 are bonded to each other with the prepregs 65 and 66 by thermal compression to form the multilayer printed circuit board 50.

In this one-stage process for producing the multilayer printed circuit board, the conductive layers are connected to each other with copper paste, tin-lead solder, a high-melting-point solder, or the like. The copper paste containing a reducing agent is not suitable for the production of printed circuit boards having fine patterns.

Lead in the tin-lead solder adversely affects human organisms and the environment. Furthermore, its eutectic solder has a low melting point of 183° C. The volume of the eutectic expands by melting during surface mounting of electronic components. The melting and expansion of the eutectic solder inhibit reliable electrical connection between the conductive layers of the multilayer printed circuit board.

On the other hand, the high-melting-point solder must be melted at a high temperature for connecting the conductive layers. The copper-lined core substrate is not durable at such a high temperature.

### SUMMARY OF THE INVENTION

An object of the present invention is to provide a multilayer printed circuit board having enhanced heat resistance and enhanced reliability by using a solder that is formed during a process for making the multilayer printed circuit board and does not melt during surface mounting of electronic components.

Another object of the present invention is to provide a method for making the multilayer printed circuit board.

According to a first aspect of the present invention, a multilayer printed circuit board comprises a plurality of core substrates having conductor patterns, the plurality of core substrates being laminated such that the conductor patterns of adjacent core substrates face each other; at least one insulating layer provided between the plurality of core substrates, the insulating layer insulating the conductor patterns from each other; and at least one connection between the plurality of core substrates, the connection connecting the conductor patterns with each other, the connection comprising an alloy comprising a first metal having a melting point below the heat resistant temperature of the plurality of core substrates and a second metal having a melting point above the heat resistant temperature of the plurality of core substrates.

According to a second aspect of the present invention, a method for making a printed circuit board comprises the steps of forming a first conductor pattern on one face and a second conductor pattern on the other face of each of a plurality of core substrates; forming a first metal layer comprising a first metal on the first conductor pattern and a second metal layer comprising a second metal on the second conductor pattern of each of the plurality of core substrates, the first metal having a melting point below the heat resistant temperature of the core substrates and the second metal having a melting point above the heat resistant temperature of the core substrates; laminating the plurality of core substrates such that the first metal layer on the first conductor pattern of one of the plurality of core substrates faces the second metal layer on the second conductor pattern of the adjacent core substrate; and bonding the first metal layer and the second metal layer by thermal compression to form an alloy layer comprising the first metal and the second metal.

At the connection. connecting the conductor patterns on the core substrates with each other, an alloy composed of the low-melting-point metal having a melting point below the heat resistant temperature of the core substrates and the high-melting-point metal having a melting point above the heat resistant temperature of the core substrate is formed. More specifically, at the connection, this alloy is formed by diffusion of the low-melting-point metal that melts at a temperature below the heat resistant temperature of the core substrates into the high-melting-point metal. Since the resulting alloy has a melting point above the heat resistant temperature of the core substrates, the alloy does not melt at a flow or reflow soldering temperature for mounting electronic components onto the outer conductor patterns, resulting in reliable electrical connection between the conductor patterns. The connection having an increased melting point enhances connection reliability of the conductor patterns in high-temperature environment.

### BRIEF DESCRIPTION OF THE DRAWINGS

FIG. 1 is a cross-sectional view of a multilayer printed circuit board according to the present invention;

FIGS. 2(A) and 2(B) are partial cross-sectional views of a connection of the multilayer printed circuit board;

FIG. 3 is a graph showing a change in melting point of a tin-silver alloy system;

FIG. 4 is a graph showing a change in melting point of a tin-zinc alloy system;

FIG. 5 is a graph showing a change in melting point of a tin-copper alloy system;

FIG. 6 is a graph showing a change in melting point of a tin-gold alloy system;

FIG. 7 is a cross-sectional view for illustrating the measurement of binding strength of a multilayer printed circuit board according to the present invention;

FIG. 8 is a cross-sectional view for illustrating the measurement of binding strength of a multilayer printed circuit board according to the present invention;

FIG. 9 is a cross-sectional view showing connections of a multilayer printed circuit board according to the present invention; and

FIGS. 10(A) to 10(C) are cross-sectional views illustrating a method for making a known multilayer printed circuit board by a one-stage process.

### DESCRIPTION OF THE PREFERRED EMBODIMENTS

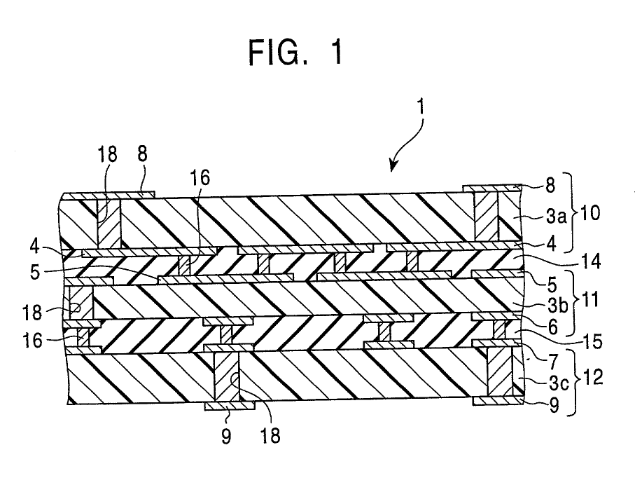

An exemplary multilayer printed circuit board according to the present invention will now be described with reference to the attached drawings. Referring to FIG. 1, the multilayer printed circuit board 1 according to the present invention has six conductive layers. The multilayer printed circuit board 1 includes core substrates 10 to 12, insulating layers 14 and 15, and connections 16 formed in the insulating layers 14 and 15. The core substrates 10 to 12, respectively, include bases 3a to 3c. Furthermore, the core substrate 10 includes an inner conductor pattern 4 and an outer conductor pattern 8, the core substrate 11 includes inner conductor patterns 5 and 6, and the core substrate 12 includes an inner conductor pattern 7 and an outer conductor pattern 9. The conductor pattern 4 faces the conductor pattern 5 and the conductor pattern 6 faces the conductor pattern 7. The insulating layer 14 insulates the conductor pattern 4 from the conductor pattern 5 and the insulating layer 15 insulates the conductor pattern 6 from the conductor pattern 7. The connections 16 electrically connect the opposing conductor patterns 4 and 5 and connect the opposing conductor patterns 6 and 7.

The core substrates 10 to 12 each is a copper-lined laminate formed by laminating copper foils onto two faces of an insulating base composed of glass-epoxy or the like. A circuit pattern is exposed onto each copper foil, developed, and etched to form the inner conductor patterns 4 to 7 and the outer conductor patterns 8 and 9. Each of the core substrates 10 to 12 has plated through holes 18 for electrical connection between the conductor patterns 4 to 9 at predetermined positions. The plated through holes 18 are formed by forming through holes at the predetermined positions of the bases 3a to 3c by drilling or laser processing and plating the interiors of the holes with copper by electro- or electroless-plating.

The insulating layers 14 and 15 are formed by placing insulating thermosetting resin prepregs such as epoxy prepregs between the core substrates 10 to 12 and compressing the laminate with heat. Thus, the insulating layers 14 and 15 bond these core substrates 10 to 12 to each other and insulate the core substrates 10 to 12 from each other.

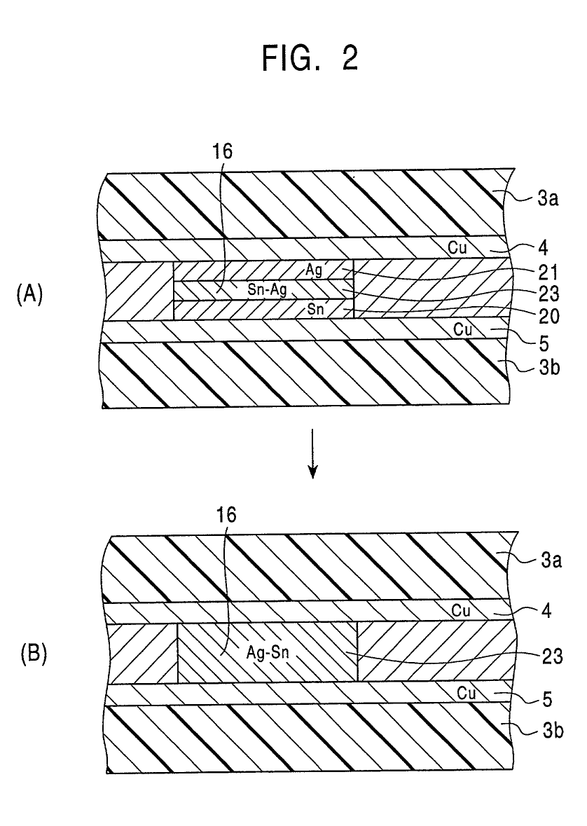

The connections 16 are each composed of an alloy containing a first metal having a melting point below the heat resistant temperature of the core substrates 10 to 12 (low-melting-point metal) and a second metal having a melting point above the heat resistant temperature of the plurality of core substrates 10 to 12 (high-melting point metal). Referring to FIGS. 2(A) and 2(B), the connection 16 between the conductor patterns 4 and 5 will be exemplified. The connection 16 is formed as follows: One of the high-melting-point metal and the low-melting-point metal is plated at a predetermined position of the conductor pattern 4 to form a bump (first bump) and the other is plated at a predetermined position of the conductor pattern 5 to form another bump (second bump). The first bump and the second bump are brought into contact with each other and are bonded to each other by heat.

The low-melting-point metal has a melting point below the heat resistant temperature of the core substrates 10 to 12, for example, less than 260° C. The high-melting-point metal has a melting point above the heat resistant temperature, for example, more than 260° C., which is a temperature during flow soldering or reflow soldering for mounting electronic components onto the outer conductor patterns.

An alloy of the high-melting-point metal and the low-melting-point metal near the eutectic point has a melting point below the melting point of the low-melting-point metal. The low-melting-point metal, which melts at a temperature below the heat resistant temperature of the core substrates 10 to 12, is used to form one of the bumps. The core substrates 10 to 12 are heated at a temperature below the heat resistant temperature so that the low-melting-point metal is diffused into the high-melting-point metal. The alloy is thereby formed. The connection 16 is formed at a temperature below the heat resistant temperature in such a manner.

As the proportion of the high-melting-point metal increases in the alloy, the melting point of the alloy of the low-melting-point metal and the high-melting-point metal in the connection 16 shifts towards the melting point of the high-melting-point metal. The proportion of the high-melting-point metal provided at the other bump is higher than that of the low-melting-point metal provided at one bump in the present invention. Thus, the resulting alloy has a melting point above the heat resistant temperature of the core substrates 10 to 12. Accordingly, the alloy at the connection 16 does not melt during flow soldering or reflow soldering for mounting electronic components onto the conductor patterns 8 and 9, ensuring electrical connection of the conductor patterns 8 and 9. Furthermore, the connection 16 having an increased melting point enhances connection reliability of the conductor patterns 4 to 9 of the multilayer printed circuit board 1 at high-temperature environments.

More specifically, as shown in FIG. 2(A), a plated tin bump 20 is formed on the conductor pattern 5 and a plated silver bump 21 is formed on the conductor pattern 4. the plated tin bump 20 and the plated silver bump 21 are brought into contact with each other and are heated to form the connection 16. Tin of the plated tin bump 20 on the conductor pattern 5 has a melting point of 231.97° C., which is lower than the melting point 961.93° C. of the plated silver bump 21 and lower than the heat resistant temperature 260° C. of the core substrates 10 to 12.

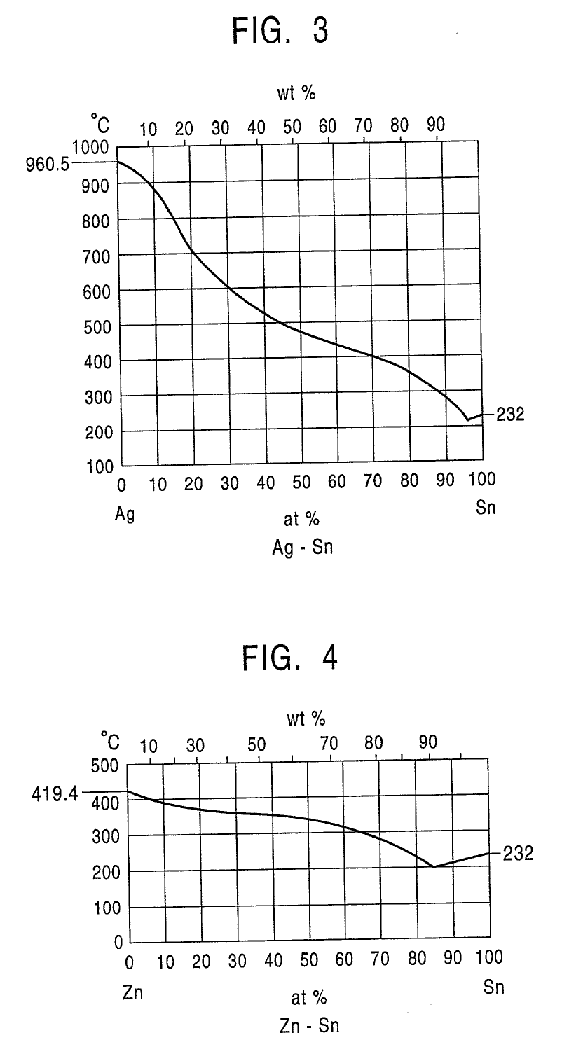

The tin of the plated tin bump 20 melts at a temperature above 231.97° C. and is diffused into the plated silver bump 21 in contact with the plated tin bump 20. Thus, in the connection 16, an alloy layer 23 composed of tin and silver is formed at the interface between the plated tin bump 20 and the plated silver bump 21 at a temperature below the heat resistant temperature 260° C. of the core substrates 10 to 12. The alloy layer 23 may have a melting point above a temperature during flow soldering or reflow soldering by adjusting the amount of tin diffused into the plated silver bump 21. Referring to FIG. 3, the alloy has a melting point of 260° C. when the Sn:Ag ratio by weight is 93:7, and the melting point increases as the silver content increases.

Referring to FIG. 1, the connections 16 of the Ag—Sn alloy layer 23 are formed at a temperature below the heat resistant temperature of the core substrates 10 to 12 and do not melt at a flow or reflow soldering temperature for mounting electronic components onto the conductor patterns 8 and 9, ensuring electrical connection of the conductor patterns 4 to 9. Furthermore, an increase in the melting point of the alloy constituting the connection 16 enhances connection reliability of the conductor patterns 4 to 9 of the multilayer printed circuit board 1 at high-temperature environments.

At the connection 16, the tin-silver alloy electrically connects the conductor pattern 4 with the conductor pattern 5. The melting point of the connection 16 becomes higher than the heat resistant temperature of the core substrate by the formation of the tin-silver alloy. In the multilayer printed circuit board 1, the connections 16 do not melt at a flow soldering or reflow soldering temperature, which should be lower than the heat resistant temperature of the core substrates, for mounting electronic components onto the outer conductor patterns 8 and 9, maintaining the electrical connection between the conductor patterns 4 to 7. Furthermore, an increase in the melting point of the connections 16 enhances connection reliability of the conductor patterns 4 to 9 of the multilayer printed circuit board 1 at high-temperature environments.

In the above embodiment, the alloy is composed of silver and tin. In the present invention, however, any other combination of metals may be used as long as these metals can be bonded to each other at a temperature below the flow or reflow soldering temperature and forms an alloy having a melting point above the flow or reflow soldering temperature.

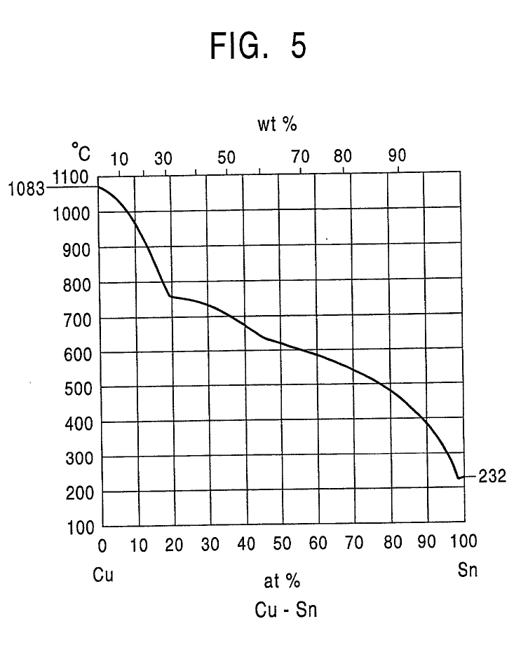

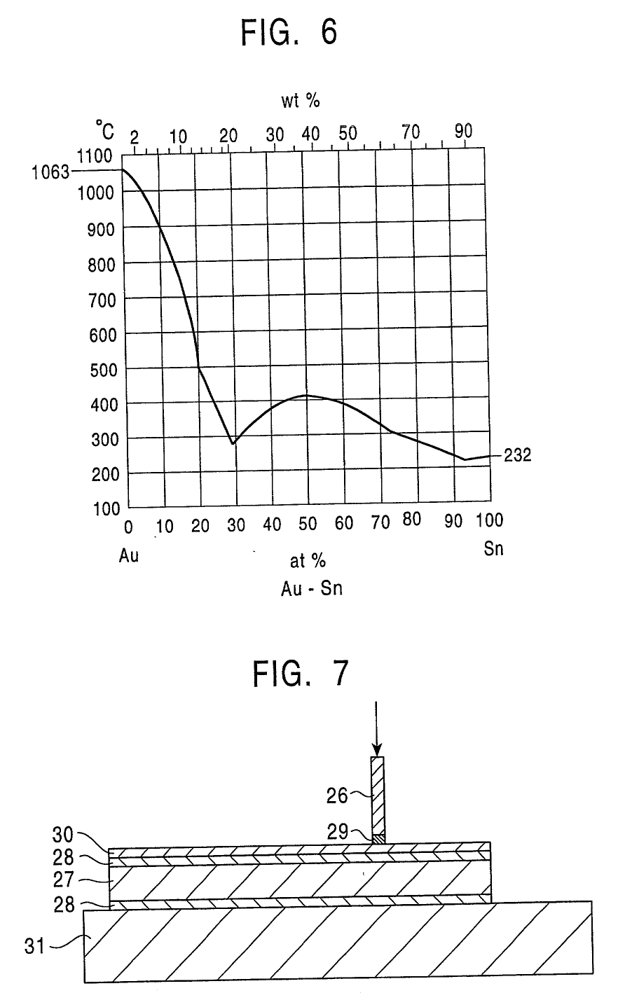

For example, the connection 16 may be formed with an Sn—Zn alloy composed of tin and zinc (melting point: 415° C.), an Sn—Cu alloy composed of tin and copper (melting point: 1,083° C.), or an Sn—Au alloy composed of tin and gold (melting point: 1,0630° C.). The Sn—Zn alloy has a melting point above 260° C. when the zinc content is higher than 16 percent by weight as shown in FIG. 4, the Sn—Cu alloy has a melting point above 260° C. when the copper content is higher than 2 percent by weight as shown in FIG. 5, and the Sn—Au alloy has a melting point above 260° C. when the gold content is higher than 23 percent by weight as shown in FIG. 6.

The metal plated bump formed on each of the conductor patterns 4 to 7 may be composed of a single metal or two or more metals. For example, the connection 16 may be formed of an alloy of Sn₉₁Zn₉ and zinc. In such a case, tin and zinc forms an eutectic crystal at the ratio Sn₉₁Zn₉:Zn=92:8 by weight, and the alloy has a melting point above 260° C. when the zinc content is higher than the above ratio.

A method for making the multilayer printed circuit board will now be described with reference to FIG. 1. The multilayer printed circuit board 1 is produced by laminating core substrates having the conductor patterns 4 to 9 and insulting resin prepregs and compressing the laminate by heat.

Copper foils are bonded to two faces of an epoxy-glass fiber substrate to form a copper-lined laminate. Through holes are formed at predetermined positions in the copper-lined laminate by drilling or laser processing and smears are removed from the through holes. The surfaces of the copper foils and the inner walls of the through holes are plated with copper by electroless plated to form conductive layers. The copper-lined laminate thereby has plated through holes 18 for electrically connecting the conductor patterns 4 to 9 on the core substrates 10 to 12.

Next, the inner conductor patterns 4 to 7 and the outer conductor patterns 8 and 9 are formed in the respective copper foils of the copper-lined laminates by exposing, developing, and etching the plated layers and the copper foils. The conductor patterns 8, 5, and 7 are electrically connected to the conductor patterns 4, 6, and 9, respectively, the plated through holes 18 extending through the core substrates 10 to 12.

First bumps of a low-melting-point metal having a melting point below the heat resistant temperature of the core substrates 10 to 12 are formed at predetermined positions of the core substrates 10 to 12 and second bumps of a high-melting-point metal having a melting point above the heat resistant temperature of the core substrates 10 to 12 are formed at predetermined positions of the core substrates 10 to 12, by plating or the like. More specifically, bumps 20 of tin having a low melting point is formed on the conductor patterns 5 and 7 and bumps 21 of silver having a high melting point is formed on the conductor patterns 4 and 6.

The core substrates 10 to 12 are laminated with epoxy resin prepregs such that the plated tin bumps 20 on the conductor patterns 5 and 7 come into contact with the plated silver bumps 21 on the conductor patterns 4 and 6, respectively. The core substrates 10 to 12 are compressed at about 130° C. for 30 minutes to form the insulating layers 14 and 15, which insulate the conductor patterns 4 and 6 from the conductor patterns 5 and 7, respectively, by the curing of the prepregs. The core substrates 10 to 12 are heated at a temperature above 231.97° C. and below 260° C under a pressure so that the tin in the plated tin bump 20 is diffused into the plated silver bump 21. As a result, as shown in FIG. 2(A), an alloy layer of tin and silver is formed at the interface between the plated tin bump 20 and the plated silver bump 21. The conductor patterns 4 and 6 are thereby connected to the conductor patterns 5 and 7 by the connections 16.

The alloy layer 23 is composed of tin and silver and has a melting point above 260° C. Thus, the alloy layer 23 does not melt during the flow or reflow soldering process for mounting electronic components onto the conductor patterns 8 and 9, ensuring the electrical connection between the conductor patterns. Since the alloy layer 23 has an increased melting point, electrical connection between conductive layers is maintained at high-temperature environments.

A cream solder is applied onto the pads on the outer conductor patterns 8 and 9 through a patterned screen. In the case of double side mounting, an adhesive is applied so that components to be mounted are not detached from the core substrates 10 to 12, if necessary. Various surface mount devices are mounted onto the respective pads and through-hole mount devices are mounted into the through holes. The core substrates 10 to 12 are transferred to and are heated in a hot air furnace and an infrared furnace at about 260° C. to fix the mount devices by soldering. The multilayer printed circuit board 1 is thereby produced.

The mounted stated and the soldered state of the resulting multilayer printed circuit board 1 are inspected by visual inspection and with an appearance tester, and are subjected to a connection test for conductive layers and an electrical operation test using testers.

Examples of the method for forming the multilayer printed circuit board according to the present invention will now be described. Referring to FIG. 7, in a first example, a 10-μm long tin portion 29 functioning as a low-melting-point metal layer was formed on the tip of a copper wire 26 with a diameter of 1.0 mm by plating, whereas a 10-μm thick silver layer 30 functioning as a high-melting-point metal layer was formed on a copper foil 2.8 of a core substrate 27 by plating. The tin portion 29 was brought into contact with the silver layer 30 and the opposite face of the core substrate 27 was heated on a hot plate 31 at 260° C. for 2 minutes, while a pressure of 500 gf was applied to the copper wire 26 with a flip chip bonder. The tin portion 29 was thereby bonded to the plated silver layer 30 of the core substrate 27.

The shear stress of the copper wire 26 connected to the core substrate 27 was about 1,700 gf. This sample was subjected to a thermal shock test of 216 cycles (for about 72 hours), each cycle including maintaining at −25° C. for 9 minutes, at room temperature for 1 minute, and at 260° C. for 9 minutes. The shear stress did not decrease during the test.

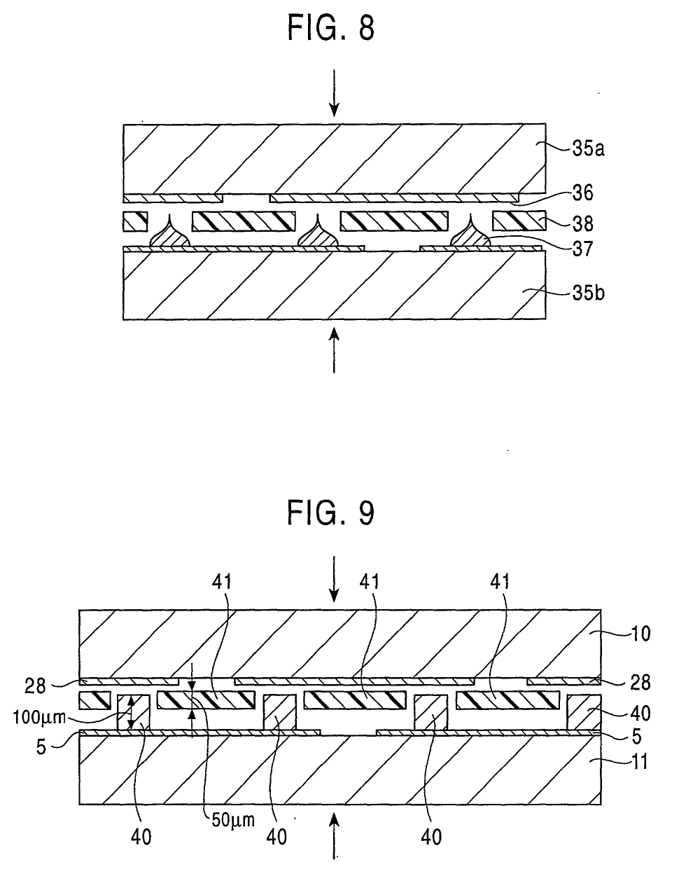

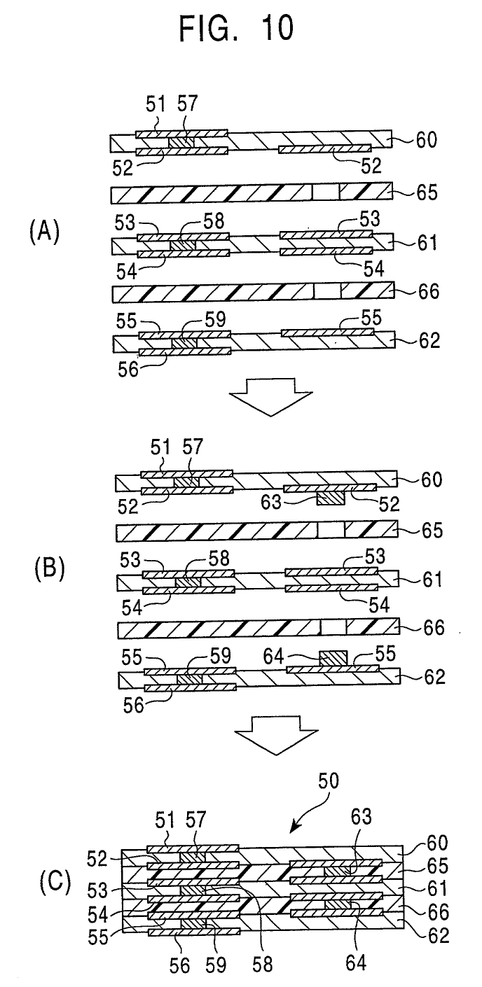

Referring to FIG. 8, in a second example, 10-μm thick tin-lead (Sn—Pb) solder layers 36 were formed on a 12-μm thick copper foil bonded to a core substrate 35a by coating, whereas 100- to 120-μm thick gold (Ag) stud bumps 37 were formed on a 12-μm thick copper foil bonded to a core substrate 35b. The core substrates 35a and 35b were laminated with a 50-μm prepreg 38 therebetween such that the tin-lead solder layer 36 came into contact with the gold bumps 37, and these were bonded to each other by thermal compression. The core substrates 35a and 35b were heated at 180° C. for 90 minutes. During this process, each tin-lead solder layer 36 was diffused into the corresponding gold bump 37 to form a ternary alloy of tin, lead, and gold.

The sample was subjected to the thermal shock test. The bonding strength at the interfaces between the gold bumps 37 and the tin-lead solder layers 36 was insufficient. Accordingly, this combination exhibited low bonding force regardless of an increased melting point.

In the multilayer printed circuit board according to the above embodiments, an alloy layer having a high melting point is formed by thermal bonding of metal bumps as the connections 16 at predetermined positions of core substrates having conductor patterns. Alternatively, metal bumps may be formed only on one core substrate so that connections are formed between the metal bump and conductive patterns formed on another core substrate.

An embodiment of the formation of the connections 16 shown in FIG. 1 will be described. Referring to FIG. 9, a copper foil bonded to a core substrate 10 is etched to form a conductor pattern, and plated tin layers 28 with a thickness of 10 μm are formed at predetermined positions of the conductor pattern. A conductor pattern 5 is formed on a core substrate 11 by etching a copper foil bonded to the conductor pattern 5. Plated copper bumps 40 with a thickness of 100 μm are formed at predetermined positions of the conductor pattern 5 by electroplating. A prepreg 41 with a thickness of 50 μm is placed between the core substrate 10 and the core substrate 11 such that the plated tin layers 28 on the core substrate 10 come into contact with the plated copper bumps 40. These are bonded by thermal compression.

The plated tin layers 28 melt at a temperature above 231.97° C. and the tin in the layers is diffused into the plated copper bumps 40. Thus, at the connections, alloy layers 42 composed of tin and copper are formed at the interfaces between the plated tin layers 28 and plated copper bumps 40 at a temperature below 260° C., which is the heat resistant temperature of the core substrates 10 to 12.

The composition of the plated tin layers 28, which is diffused into the plated copper bumps 40, is controlled so that the alloy layers 42 have a melting point above the flow or reflow processing temperature. More specifically, the ratio of tin and copper constituting the alloy layers 42 is adjusted so that the melting point becomes higher than 260° C., according to FIG. 5.

As a result, the connections 16 of the Cu—Sn alloy layers 42 can be formed at a temperature below the heat resistant temperature of the core substrates 10 to 12 and do not melt at the flow or reflow soldering temperature for mounting electronic components into the outer conductor patterns 8 and 9, ensuring electrical connections of the conductor patterns 4 to 9. Such an increase in the melting point at the connections 16 also contributes to high connection reliability of the conductor patterns 4 to 9 in high-temperature environments.

According to the multilayer printed circuit board and the method for making the multilayer printed circuit board of the present invention, the connections 16 for connecting the conductor patterns 4 to 9 formed on the core substrates 10 to 12 are formed of an alloy composed of a low-melting-point metal having a melting point below the heat resistant temperature of the core substrates 10 to 12 and a high-melting-point metal having a melting point above the heat resistant temperature of the core substrates 10 to 12.

The low-melting-point metal at the connections 16 melts and diffused into the high-melting-point metal at a temperature below the heat resistant temperature of the core substrates 10 to 12 to form an alloy having a higher melting point. The alloy at the connections 16 does not melt at the flow or reflow soldering temperature for mounting electronic components onto the conductor patterns 8 and 9, ensuring electrical connections between the conductor patterns. Furthermore, the connections 16 having a higher melting point ensure connection reliability between the conductor patterns of the multilayer printed circuit board 1 in high-temperature environments.

In the above embodiments, the multilayer printed circuit board is of a rigid type. The present invention can also be applied to flexible multilayer printed circuit boards and methods for making the same.

What is claimed is:

1. A multilayer printed circuit board comprising:
a plurality of core substrates having conductor patterns, the plurality of core substrates being laminated such that the conductor patterns of adjacent core substrates face each other;
at least one insulating layer provided between the plurality of core substrates, the insulating layer insulating the conductor patterns from each other; and
at least one connection between the plurality of core substrates, the connection connecting the conductor patterns with each other, the connection comprising an alloy comprising a first metal having a melting point below the heat resistant temperature of the plurality of core substrates and a second metal having a melting point above the heat resistant temperature of the plurality of core substrates.

2. A multilayer printed circuit board according to claim 1, wherein the connection is formed by thermal compression bonding of a bump of the first metal formed on a conductor pattern of one of the adjacent core substrates to a bump of the second metal formed on a conductor pattern of the other core substrate.

3. A multilayer printed circuit board according to claim 1, wherein the connection is formed by thermal compression bonding of a bump of one of the first metal and the second metal formed on the conductor pattern of one of the adjacent core substrates to a metal layer of the other of the first metal and the second metal formed on the conductor pattern of the other core substrate.

4. A multilayer printed circuit board according to claim 1, wherein the first metal is tin and the second metal is selected from the group consisting of silver, zinc, copper, and gold.

5. A method for making a printed circuit board comprising the steps of:
forming a first conductor pattern on one face and a second conductor pattern on the other face of each of a plurality of core substrates;
forming a first metal layer comprising a first metal on the first conductor pattern and a second metal layer comprising a second metal on the second conductor pattern of each of the plurality of core substrates, the first metal having a melting point below the heat resistant temperature of the core substrates and the second metal having a melting point above the heat resistant temperature of the core substrates;
laminating the plurality of core substrates such that the first metal layer on the first conductor pattern of one of the plurality of core substrates faces the second metal layer on the second conductor pattern of the adjacent core substrate; and
bonding the first metal layer and the second metal layer by thermal compression to form an alloy layer comprising the first metal and the second metal.

6. A method for making a multilayer printed circuit board according to claim 5, wherein the first metal layer and the second metal layer comprise metal bumps.

7. A method for making a multilayer printed circuit board according to claim 5, wherein one of the first metal layer and the second metal layer comprises a metal bump, and the other comprises a metal film.

8. A method for making a multilayer printed circuit board according to claim 5, wherein the first metal is tin and the second metal is selected from the group consisting of silver, zinc, copper, and gold.
